(19) United States
(12) Patent Application Publication
(10) Pub. No.: US 2006/0092719 A1
(43) Pub. Date: May 4, 2006

(54) Semiconductor memory device

(75) Inventor: Katsuyuki Fujita, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Minato-ku (JP)

(21) Appl. No.: 11/252,798

(22) Filed: Oct. 19, 2005

(30) Foreign Application Priority Data
Oct. 28, 2004 (JP) 2004-313988

(51) Int. Cl. G11C 7/10

(52) U.S. Cl. 365/189.06

(57) ABSTRACT

A semiconductor memory device has a memory cell array, first dummy bit lines, second dummy bit lines, first dummy cells each of which is connected to the corresponding first dummy bit line and generates a reference current for data “0”, second dummy cells each of which is connected to the corresponding second dummy bit line and generates a reference current for data “1”, first dummy bit line clamping circuits, second dummy bit line clamping circuits, reference potential generation circuits, sense amplifiers, and a common connecting line which connects an output terminal of the corresponding first dummy bit clamping circuit, an output terminal of the corresponding second dummy bit clamping circuit and an input terminal of the corresponding reference potential generation circuit.

### CROSS REFERENCE TO RELATED APPLICATIONS

This application claims benefit of priority under 35USC§119 to Japanese Patent Application No. 2004-313988, filed on Oct. 28, 2004, the entire contents of which are incorporated by reference herein.

### BACKGROUND OF THE INVENTION

1. Field of the Invention

The present invention relates to a semiconductor memory device which detects logics of data by a potential difference based on a current difference between an output current from a memory cell and a reference current.

2. Related Art

There is proposed a DRAM which constitutes a memory cell by using only one transistor without using a capacitor. A DRAM of this type stores data using a difference in a threshold voltage caused by a potential difference in a channel body of its transistor. More specifically, the DRAM determines data stored in each memory cell by detecting presence/absence or a magnitude of an output current from the memory cell.

There is also proposed a semiconductor memory device in which a dummy cell for generating a reference current is provided to detect an output current from a memory cell and which detects a current difference between the output current from the memory cell and the reference current, and detects logics of data based on a potential difference based on the detected current difference (see Japanese Patent Laid-Open No. 2003-68877).

Generally, dummy cells for data “0” and dummy cells for data “1” are separately provided. Also, the dummy cells are arranged at predetermined intervals in groups of a plurality of dummy cells. Variations in characteristics among the dummy cells may result in variations in the reference current, which may make it impossible to accurately determine the data logic of memory cells.

### SUMMARY OF THE INVENTION

According to one embodiment of the present invention, A semiconductor memory device, comprising:

a memory cell array which has a plurality of memory cells;

first dummy bit lines arranged at a predetermined interval by sandwiching at least one bit line therebetween;

second dummy bit lines arranged at a predetermined interval by sandwiching at least one bit line therebetween;

first dummy cells each of which is connected to the corresponding first dummy bit line and generates a reference current for data “0”;

second dummy cells each of which is connected to the corresponding second dummy bit line and generates a reference current for data “1”;

first dummy bit line clamping circuits each of which limits a potential of the corresponding first dummy bit line to be equal to or less than a predetermined potential;

second dummy bit line clamping circuits each of which limits a potential of the corresponding second dummy bit line to be equal to or less than the predetermined potential;

reference potential generation circuits each of which generates a reference potential based on output currents of the corresponding first and second dummy bit line clamping circuits;

sense amplifiers each of which detects logics of data stored in a selected memory cell based on a potential difference between an output current of the selected memory cell and the reference current; and

a common connecting line which connects an output terminal of the corresponding first dummy bit clamping circuit, an output terminal of the corresponding second dummy bit clamping circuit and an input terminal of the corresponding reference potential generation circuit.

Furthermore, according to one embodiment of the present invention, a semiconductor memory device, comprising:

a memory cell array which has a plurality of memory cells;

a plurality of bit lines connected to the memory cells;

a plurality of dummy bit lines each of which is arranged at a predetermined interval by sandwiching at least one bit line therebetween;

first dummy cells each of which is connected to the corresponding dummy bit line and generates a reference current for data “0”;

second dummy cells each of which is connected to the corresponding dummy bit line and generates a reference current for data “1”;

clamping circuits each of which limits a potential of the corresponding dummy bit line to be equal to or less than a predetermined potential;

reference potential generation circuits each of which generates a reference potential based on an output current of the corresponding clamping circuit;

sense amplifiers each of which detects logics of data stored in the selected memory cell based on the reference current and the reference potential; and

a common connecting line which connects an output terminal of the clamping circuit corresponding to the plurality of dummy bit lines and an input terminal of the corresponding reference potential generation circuit.

### BRIEF DESCRIPTION OF THE DRAWINGS

FIG. 1 is a block diagram showing a schematic configuration of a semiconductor memory device according to one embodiment of the present invention.

FIG. 2 is a cross-sectional view showing a structure of a DRAM cell 1 using an n channel MISFET.

FIG. 3 is a circuit diagram of a DRAM cell array 2.

FIG. 4 is a diagram showing a relationship between data “1” and “0”, a channel body potential and a gate voltage.

FIG. 5 is a detailed circuit diagram of FIG. 1.

FIG. 6 is a circuit diagram showing an internal configuration of an operational amplifier 45 of FIG. 5.

FIG. 7 is a diagram showing an output waveform of an output potential Vsa of a differential amplifier.

FIG. 8 is a waveform diagram showing an output waveform of a conventional sense amplifier 10.

FIG. 9 is a block diagram showing schematic configuration of a semiconductor memory device according to a second embodiment of the present invention.

FIG. 10 is a detailed circuit diagram of FIG. 9.

FIG. 11 is a block diagram showing a schematic configuration of a semiconductor memory device according to a third embodiment of the present invention.

FIG. 12 is a block diagram showing a schematic configuration of a semiconductor memory device according to a fourth embodiment of the present invention.

FIG. 13 is a block diagram showing a schematic configuration of a semiconductor memory device according to a fifth embodiment of the present invention.

FIG. 14 is a block diagram showing a schematic configuration of a semiconductor memory device according to a sixth embodiment of the present invention.

FIG. 15 is a block diagram showing a schematic configuration of a semiconductor memory device according to a seventh embodiment of the present invention.

FIG. 16 is a detailed circuit diagram of a semiconductor memory device of FIG. 15.

FIG. 17 is a block diagram showing a schematic configuration of a semiconductor memory device according to an eighth embodiment of the present invention.

### DETAILED DESCRIPTION OF THE INVENTION

A semiconductor memory device according to one embodiment of the present invention will be explained below with reference to the drawings.

### FIRST EMBODIMENT

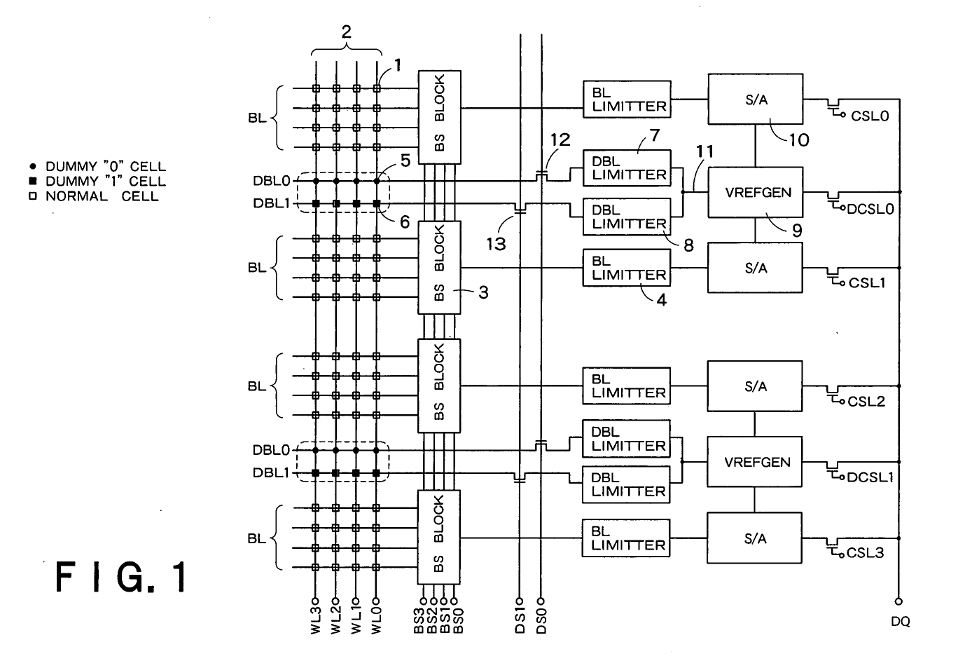

FIG. 1 is a block diagram showing a schematic configuration of a semiconductor memory device according to a first embodiment of the present invention. The semiconductor memory device in FIG. 1 includes DRAM cell arrays 2 each of which has DRAM cells 1 arranged lengthwise and crosswise, word lines WL0 to WL3 which are connected to gates of the DRAM cells 1, bit lines BL which are connected to drains of the DRAM cells 1, bit line selection circuits (BS BLOCK) 3 each of which selects one of a plurality of bit line potentials, and bit line clamping circuits (BL LIMITER) 4 which limit bit line potentials selected by the bit line selection circuits 3 so as to be equal to or less than a predetermined potential. The device further includes first dummy bit lines DBL0 for data “0” which are arranged at predetermined intervals by sandwiching a plurality of bit lines BL between them, second dummy bit lines DBL1 for data “1” which are arranged at predetermined intervals by sandwiching a plurality of bit lines BL between them, first dummy cells 5 connected to the first dummy bit lines DBL0 to generate reference currents for data “0,” and second dummy cells 6 connected to the second dummy bit lines DBL1 to generate reference currents for data “1.” The device further includes first dummy bit line clamping circuits (DBL LIMITTER) 7 each of which limits the potential of the corresponding first dummy bit line DBL0 so as to be equal to or less than a predetermined potential, second dummy bit line clamping circuits 8 each of which limits the potential of the corresponding second dummy bit line DBL1 so as to be equal to or less than a predetermined potential, reference potential generation circuits 9 each of which generates a reference potential on the basis of output currents from the corresponding first and second dummy bit line clamping circuits 7 and 8, and sense amplifiers 10 each of which detects the logic of data held by a selected one of the memory cells on the basis of a current difference between an output current from the selected memory cell and a reference current. The device further includes common connecting lines 11 each of which connects an output terminal of the corresponding first dummy bit line clamping circuit 7, an output terminal of the corresponding second dummy bit line clamping circuit 8 and an input terminal of the corresponding reference potential generation circuit 9, first transistors 12 each of which controls writing of data to corresponding ones of the first dummy cells 5, and second transistors 13 each of which controls writing of data to corresponding ones of the second dummy cells 6.

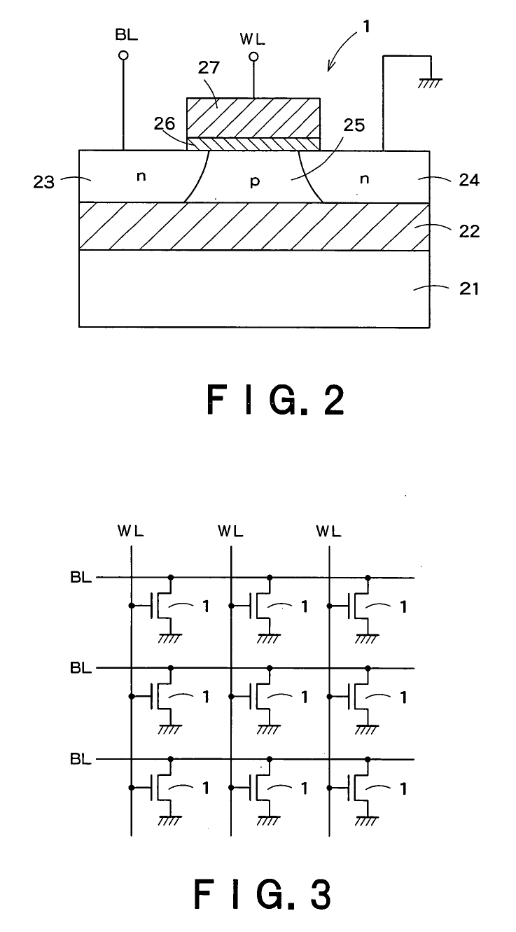

Each DRAM cell 1 is composed of one MISFET with a floating channel body. FIG. 2 is a sectional view showing a structure of the DRAM cell 1 using an n-channel MISFET. An insulating film 22 made of, e.g., a silicon oxide film is formed on a silicon substrate 21. N-diffusion layers 23 and 24 and a p-diffusion layer 25 which are separated from the silicon substrate 21 are formed on the upper surface of the insulating film 22. The n-diffusion layers 23 and 24 become a source region and drain region, respectively, while the p-diffusion layer 25 becomes a channel body. A gate (word line) 27 is formed on the upper surface of the channel body 25 through a gate insulating film 26.

FIG. 3 is a circuit diagram of each DRAM cell array 2. Gates of DRAM cells 1 which are arranged in each column are connected in common to a corresponding one of the word lines WL0 to WL3. Drains the DRAM cells 1 which are arranged in each row are connected in common to a corresponding one of the bit lines BL. Sources of all the DRAM cells 1 are set at a reference potential (ground potential). Each DRAM cell 1 has a floating channel body separated from the remaining DRAM cells 1.

Each DRAM cell 1 dynamically stores a first data state in which a p-type silicon layer functioning as the channel body is set to a first potential, and a second data state in which the p-type silicon layer is set to a second potential. More specifically, the first data state is written by applying a high-level voltage to a selected one of the word lines WL0 to WL3 and a selected one of the bit lines BL, causing a selected one of the DRAM cells 1 to operate in a pentode mode, and holding, in a channel body, a majority carrier (in the case of an n channel, holes) generated upon impact ionization in the vicinity of a drain junction. This state corresponds to, e.g., data “1.” The second data state is written by setting the selected one of the word lines WL0 to WL3 in a high-level state to increase a potential at a channel body of the selected DRAM cell 1 through capacitive coupling, setting the selected one of the bit lines BL to a low level, feeding a forward bias current to a junction between the channel body and drain of the selected DRAM cell 1 to release the majority carrier in the channel body to the drain. This state corresponds to, e.g., data “0.”

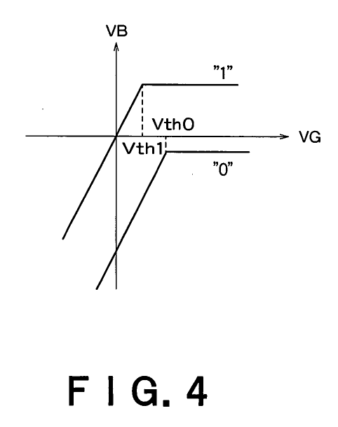

A difference between data “1” and data “0” appears as a difference in a gate threshold value of a MISFET. More specifically, a relationship between data “1” and “0,” a channel body potential, and a gate voltage is shown in FIG. 4. As a result of a substrate bias by the channel body potential, a threshold value Vth1 in the case of “1” becomes lower than a threshold voltage Vth0 in the case of “0.” Accordingly, the read-out data can be determined by detecting a difference in cell current caused by a difference in threshold voltage.

The magnitude of a cell current output from each DRAM cell 1 is determined by comparing the cell current with a reference current. As reference current sources for that purpose, the dummy cells shown in FIG. 1 are provided. The dummy cells include the first dummy cells 5, each of which generates a reference current for data “0,” and the second dummy cells 6, each of which generates a reference current for data “1.” Each of these dummy cells has the same structure and characteristics as those of the DRAM cells 1.

In this embodiment, each common connecting line 11 connects an output terminal of the corresponding first dummy bit line clamping circuit 7, an output terminal of the corresponding second dummy bit line clamping circuit 8, and an input terminal of the corresponding reference potential generation circuit 9. For this reason, a current obtained by adding up a current which flows through the corresponding first dummy cells 5 and a current which flows through the corresponding second dummy cells 6 flows through the common connecting line 11. Each reference potential generation circuit 9 generates a reference potential on the basis of a current on the corresponding common connecting line 11.

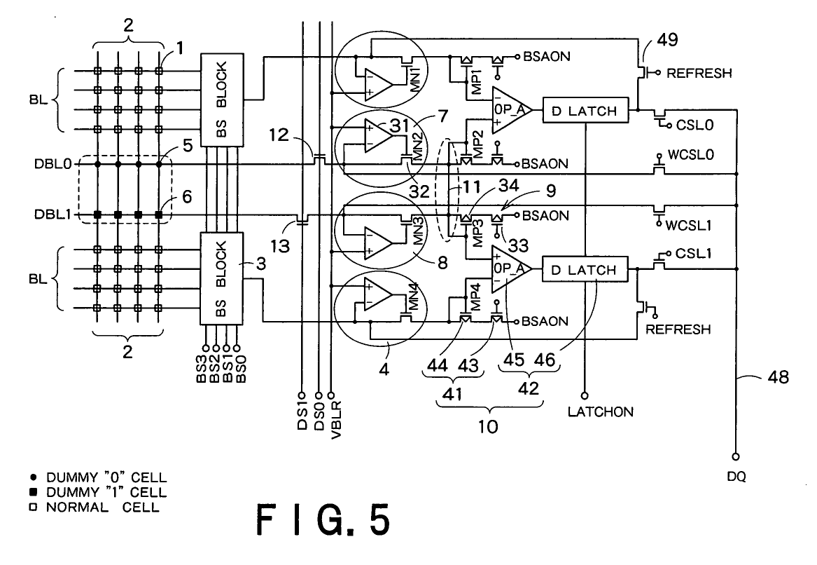

FIG. 5 is a circuit diagram showing in more detail part of the circuit diagram in FIG. 1. The first dummy bit line clamping circuits 7 and the second dummy bit line clamping circuits 8 are equivalent in size, shape, circuit configuration, and electrical properties. In the following description, the configuration and operation of the first dummy bit line clamping circuits 7 will be explained. However, the same applies to the second dummy bit line clamping circuits 8.

Each of the bit line clamping circuits 4 and first dummy bit line clamping circuits 7 is composed of an identical circuit and has an operational amplifier 31 which outputs a potential difference between the potential of the corresponding bit line (dummy bit line) and a reference potential VBLR and a transistor 32 which performs negative feedback control on the potential of the bit line (dummy bit line) in accordance with an output potential from the operational amplifier 31, as shown in FIG. 5. The transistors in the bit line clamping circuits 4 and the transistors in the first dummy bit line clamping circuits 7 have common gate width and gate length.

The reference potential VBLR is input to a (+) input terminal of each operational amplifier 31, and a corresponding one of the bit lines (dummy bit lines) is connected to a (−) input terminal. Each of the first dummy bit line clamping circuits 7 controls the potential of the corresponding first dummy bit line DBL0 so that the potential becomes equal to or less than the predetermined potential VBLR.

As shown in FIG. 5, each reference potential generation circuit 9 has two pairs of cascaded PMOS transistors 33 and 34 and generates a reference potential on the basis of an output current from the corresponding first dummy bit line clamping circuit 7. Both of a drain terminal of the PMOS transistor 33 on each first dummy bit line DBL0 and a drain terminal of the PMOS transistor 34 on the corresponding second dummy bit line DBL1 are connected to the corresponding common connecting line 11. With this configuration, the reference potential generation circuit 9 generates a reference potential based on the sum of a current which flows through the corresponding first dummy cells 5 and a current which flows through the corresponding second dummy cells 6.

Each sense amplifier 10 which senses an output current from corresponding ones of the DRAM cells 1 has a first sense circuit 41 which generates a data potential on the basis of a current difference between an output current from a selected one of the DRAM cells 1 and a reference current, and a second sense circuit 42 which detects logics of data held by the selected DRAM cell 1 on the basis of the data potential output from the first sense circuit 41 and a reference potential.

As shown in FIG. 5, each first sense circuit 41 is composed of two cascaded PMOS transistors 43 and 44. Each second sense circuit 42 has an operational amplifier 45 which outputs a signal corresponding to a potential difference between a data potential and a reference potential, and a latch circuit 46 which latches an output from the operational amplifier 45. Data held by each latch circuit 46 is transferred to a data line 48 through a column gate 47 which is driven by a column selection line.

A refresh circuit 49 for refreshing data of corresponding ones of the DRAM cells 1 in refresh cycles of a predetermined length on the basis of data held therein is connected to the output of the data line 48. At the time of readout of data “0” or “1,” each latch circuit 46 becomes a state of outputting “L” or “H”. This logic is transferred to the corresponding bit line BL through the data line.

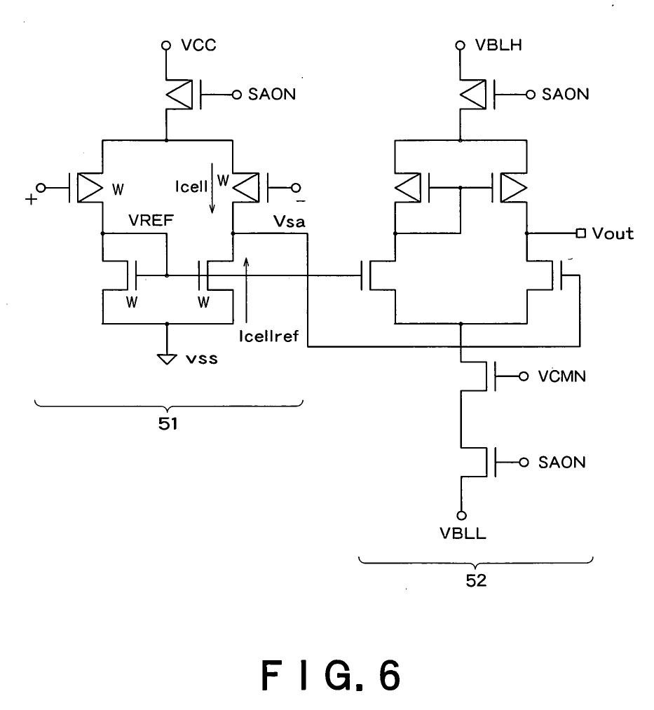

FIG. 6 is a circuit diagram showing the internal configuration of each operational amplifier 45 in FIG. 5. The operational amplifier 45 in FIG. 6 is composed of two-stage differential amplifiers 51 and 52. The differential amplifier 51 at the first stage outputs a potential difference between a potential of a (+) input terminal and that of a (−) input terminal. The differential amplifier 52 in the subsequent stage outputs a signal Vout corresponding to a potential difference between an output from the differential amplifier 51 in the first stage and a reference potential VREF.

Each sense amplifier 10 in FIG. 1 compares the current sum of a reference current I cell 1 which flows through the corresponding first dummy cells 5 for data “0” and a reference current I cell 2 which flows through the corresponding second dummy cells 6 for data “1” with twice a cell current in one of the DRAM cells 1 to be actually read out. In the case of data “0,” an output potential Vsa from the differential amplifier 51 in FIG. 6 is set to be low. On the other hand, in the case of data “1,” the output potential Vsa is set to be high.

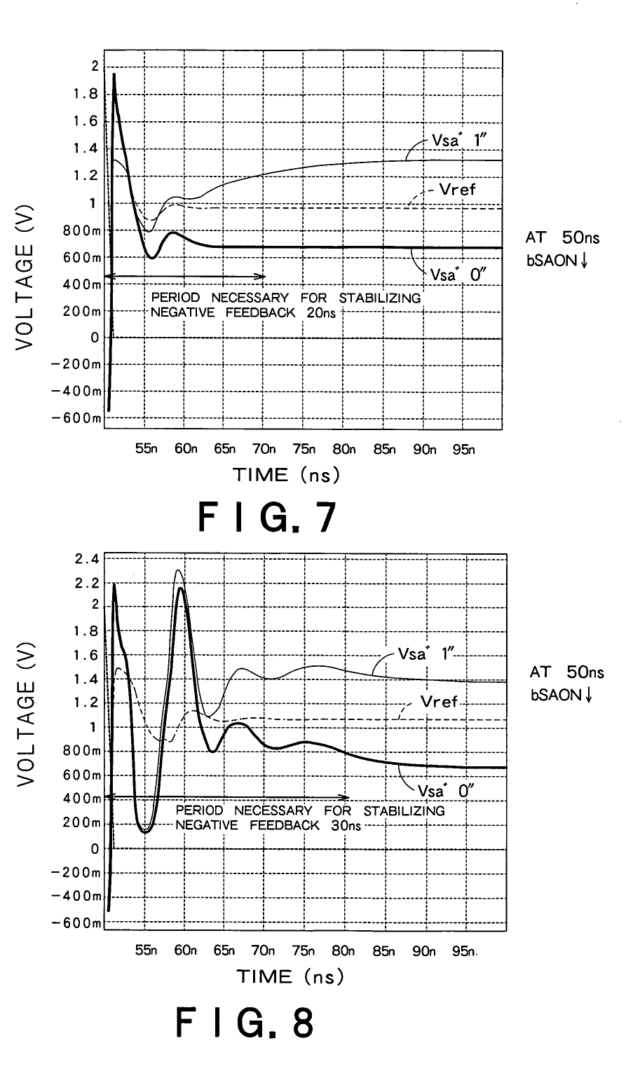

FIG. 7 is a chart showing output waveforms at the output potential Vsa of the differential amplifier. FIG. 7 shows waveforms at an output potential Vsa“0” in the case of data “0,” an output potential Vsa“1” in the case of data “1,” and the reference potential VREF. FIG. 8 is a waveform chart showing output waveforms of a conventional sense amplifier 10. As shown in FIGS. 7 and 8, the output potentials Vsa“0” and Vsa“1” unstably fluctuate for about 30 ns in the conventional case while a period for which the output potentials Vsa“0” and Vsa“1” unstably fluctuate falls within about 20 ns in this embodiment. For this reason, according to this embodiment, the output potential of each sense amplifier 10 becomes stable within a shorter period of time than the conventional case, and thus readout of data can be performed at higher speed.

As described above, according to the first embodiment, the sum of the current which flows through the first dummy cells 5 and the current which flows through the second dummy cells 6 is detected by the reference connecting line 11, and the reference potential is generated on the basis of the sum. Therefore, even if the current which flows through the first dummy cells 5 and the current which flows through the second dummy cells 6 vary from each other, the variation can be canceled out by calculating the sum. Also, the reference potential becomes free of the influence of the variation between the current which flows through the first dummy cells 5 and the current which flows through the second dummy cells 6. This makes it possible to accurately determine the data logics of the DRAM cells.

According to the first embodiment, the output potential of each sense amplifier 10 becomes stable within a short period of time, and thus high-speed readout can be performed.

### SECOND EMBODIMENT

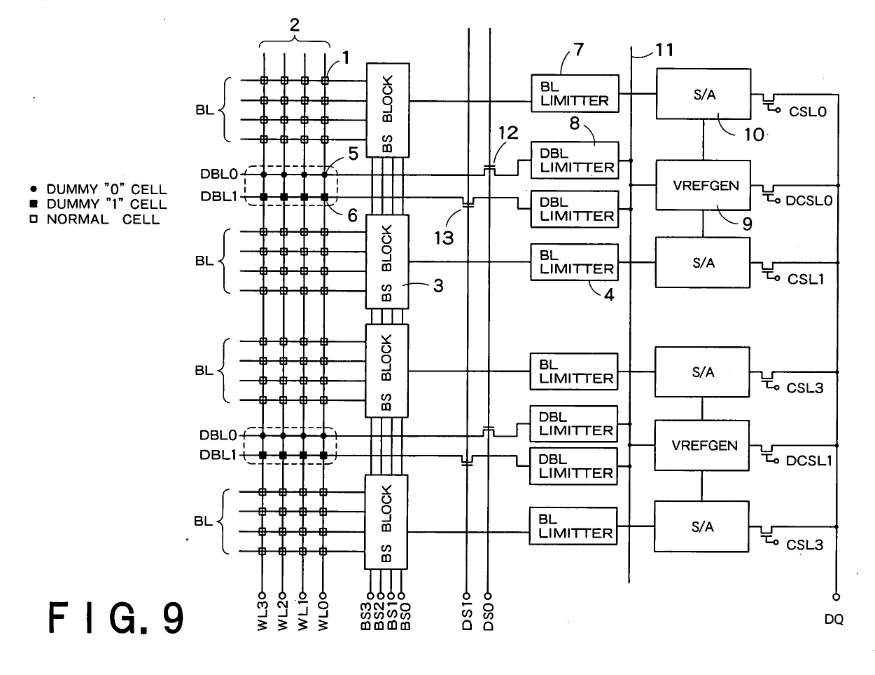

FIG. 9 is a block diagram showing the schematic configuration of a semiconductor memory device according to the second embodiment of the present invention. Ones of the components in FIG. 9 that are shared with FIG. 1 are denoted by the same reference numerals as those in FIG. 1. In the following description, an explanation will be given with a focus on differences between FIGS. 9 and 1.

In the semiconductor memory device of FIG. 1, the first dummy bit line clamping circuits 7 located distant from each other are connected to the common connecting lines 11 separate from each other. In contrast, in this embodiment, all of first and second dummy bit line clamping circuits 7 and 8 and all of reference potential generation circuits 9 are connected to a single common connecting line 11.

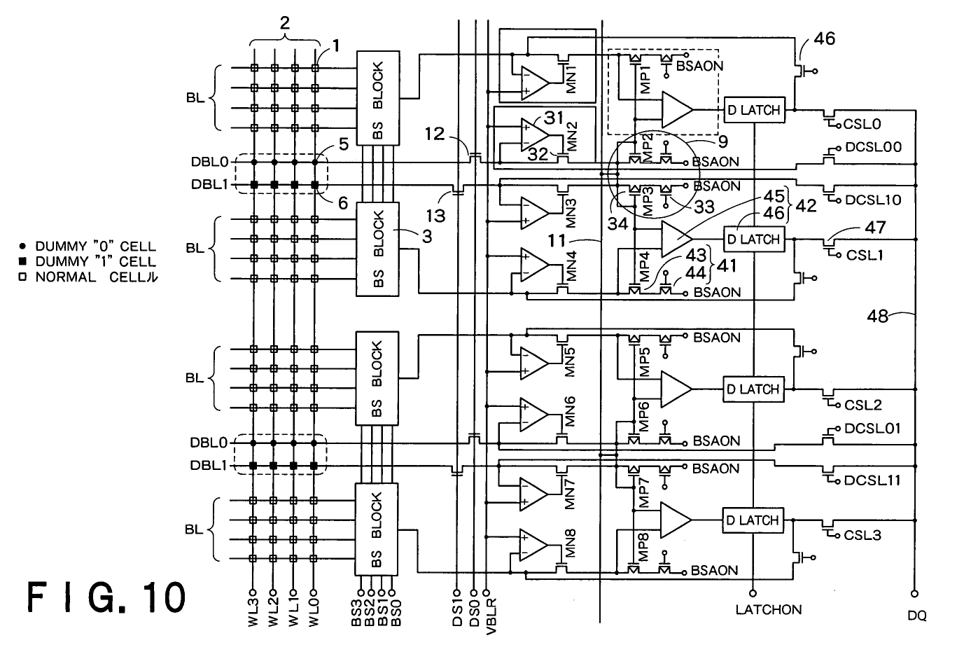

FIG. 10 is a circuit diagram showing in more detail the circuit diagram in FIG. 9. A difference from FIG. 5 lies in that drain terminals of PMOS transistors 34 within the plurality of reference potential generation circuits 9 are connected to the common connecting line 11. With this configuration, the sum of output currents from a plurality of first dummy bit lines DBL0 and output currents from a plurality of second dummy bit lines DBL1 flows to the common connecting line 11, and variation between currents which flow through first dummy cells 5 and currents which flow through second dummy cells 6 can be canceled out more reliably. Accordingly, a reference potential generated by each reference potential generation circuit 9 becomes free of the influence of the variation between the currents which flow through the first dummy cells 5 and the currents which flow through the second dummy cells 6.

### THIRD EMBODIMENT

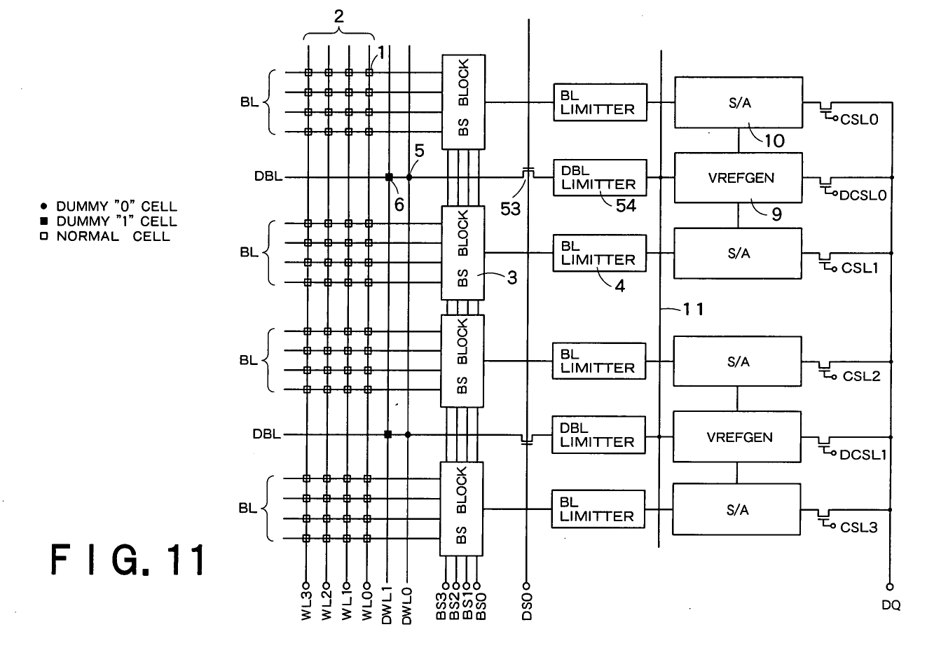

FIG. 11 is a block diagram showing the schematic configuration of a semiconductor memory device according to a third embodiment of the present invention. Ones of the components in FIG. 11 that are shared with FIG. 1 are denoted by the same reference numerals as those in FIG. 1. In the following description, an explanation will be given with a focus on differences between FIGS. 11 and 1.

The semiconductor memory device in FIG. 11 has word lines DWL0 and DWL1 (to be referred to as dummy word lines DWL0 and DWL1 hereinafter) dedicated to first dummy cells 5 for data “0” and second dummy cells 6 for data “1.” Each first dummy cell 5 and the corresponding second dummy cell 6 are connected to a single dummy bit line DBL. These pairs of the first and second dummy cells 5 and 6 are arranged at predetermined intervals with a plurality of bit lines BL between adjacent ones of the pairs.

A transistor 53 which controls writing of data to the corresponding first and second dummy cells 5 and 6 and a dummy bit line clamping circuit 54 are connected to each dummy bit line DBL. Gates of the plurality of transistors 53 corresponding to the plurality of dummy bit lines are connected to a common selection line DS0, and output terminals of the plurality of dummy bit line clamping circuits 54 are connected to a common connecting line 11. Internal configurations of the reference potential generation circuits and the sense amplifiers 10 are the same as those in FIG. 5.

As described above, according to third embodiment, the output terminals of the plurality of dummy bit line clamping circuits 4 are connected to the common connecting line 11. The sum of currents which flow through the dummy cells flows to the common connecting line 11, and thus variation between the currents which flow through the dummy cells can be canceled out. As compared to the first and second embodiments, the number of dummy cells and that of transistors for controlling writing to the dummy cells can be reduced. This enables a reduction in chip size.

### FOUR EMBODIMENT

A set of first dummy cells 5 for data “0” and a set of second dummy cells 6 for data “1” are arranged separately from each other by sandwiching DRAM cells 1 between them.

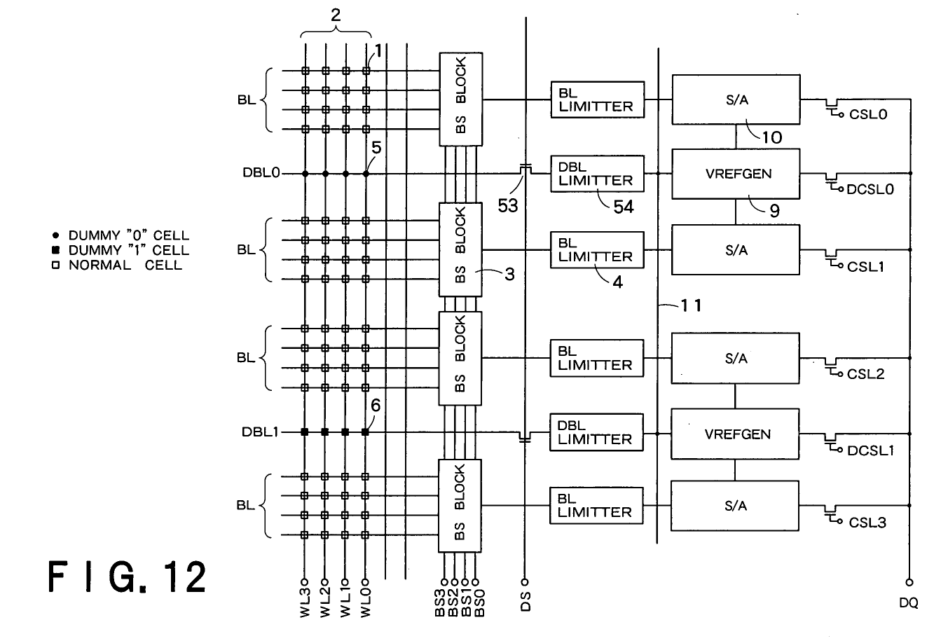

FIG. 12 is a block diagram showing the schematic configuration of a semiconductor memory device according to a four embodiment of the present invention. Ones of the components in FIG. 12 that are shared with FIG. 1 are denoted by the same reference numerals as those in FIG. 1. In the following description, an explanation will be given with a focus on differences between FIGS. 12 and 1.

In the semiconductor memory device of FIG. 12, the first dummy cells 5 connected to a first dummy bit line DBL0 for data “0” and the second dummy cells 6 connected to a second dummy bit line DBL1 for data “1” are arranged by sandwiching the DRAM cells 1 between them. A transistor 55 which controls writing of data to the first dummy bit line DBL0, a first dummy bit line clamping circuit 7, and a first reference potential generation circuit 9 are connected to the first dummy bit line DBL0. A transistor 56 which controls writing of data to the second dummy bit line DBL1, second dummy bit line clamping circuit 8, and a second reference potential generation circuit 9 are connected to the second dummy bit line DBL1.

An output terminal of the first dummy bit line clamping circuit 7, an output terminal of the second dummy bit line clamping circuit 8, an input terminal of the first reference potential generation circuit 9, and an input terminal of the second reference potential generation circuit 9 are all connected to a common connecting line 11. Therefore, even if a current which flows through the first dummy cells 5 and a current which flows through the second dummy cells 6 vary from each other, the variation can be canceled out by calculating the sum of the currents. A reference potential becomes free of the influence of the variation between the currents which flow through the first dummy cells 5 and second dummy cells 6.

### FIFTH EMBODIMENT

A fifth embodiment is a modification of the fourth embodiment. The number of dummy cells in the fifth embodiment is made smaller than that in the fourth embodiment.

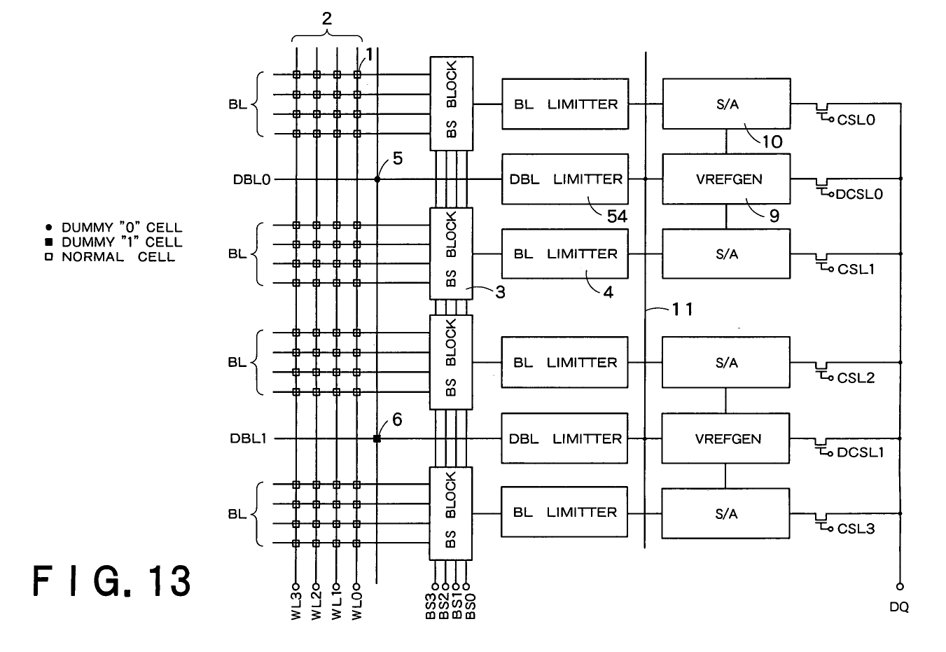

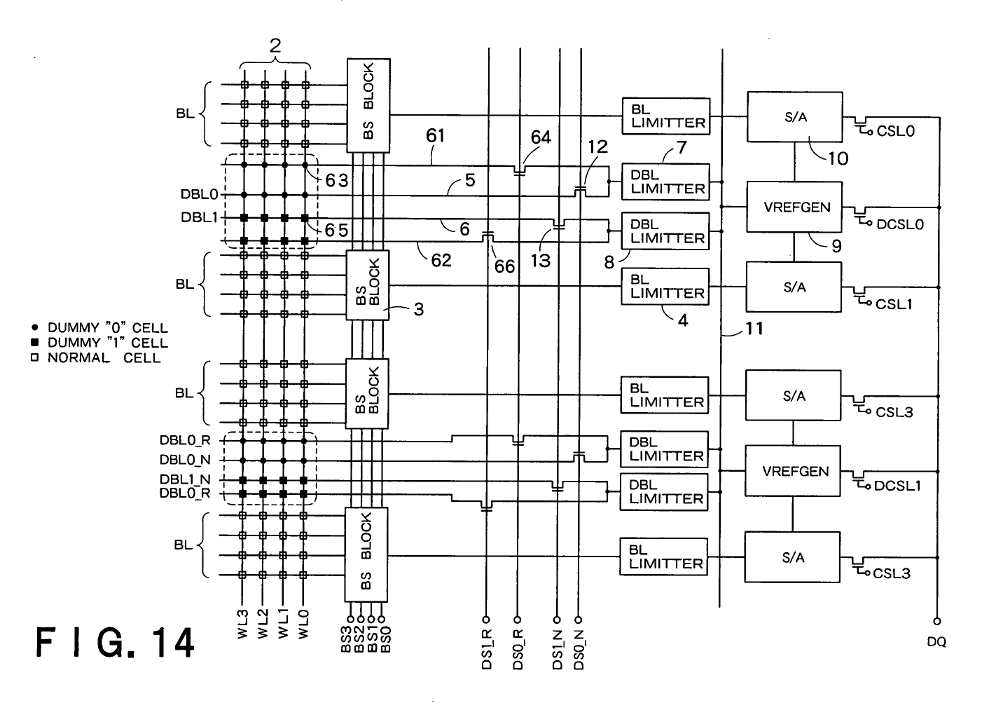

FIG. 13 is a block diagram showing a schematic configuration of a semiconductor memory device according to the fifth embodiment of the present invention. the components in FIG. 13 that are shared with FIG. 1 are denoted by the same reference numerals as those in FIG. 1. In the following description, an explanation will be given with a focus on differences between FIGS. 13 and 1.

The semiconductor memory device in FIG. 13 includes a dummy word line DWL to which a first dummy cell 5 for data “0” and a second dummy cell 6 for data “1” are connected, in addition to word lines WL0 to WL3 to which DRAM cells 1 are connected. A first dummy bit line DBL0 to which the first dummy cell 5 is connected and a second dummy bit line DBL1 to which the second dummy cell 6 is connected are arranged separately from each other by sandwiching bit lines BL for the DRAM cells 1 between them.

An output terminal of a first dummy bit line clamping circuit 7 which is connected to the first dummy bit line DBL0, an output terminal of a second dummy bit line clamping circuit 8 which is connected to the second dummy bit line DBL1, a first reference potential generation circuit 9, and a second reference potential generation circuit 9 are all connected to a common connecting line 11. With this configuration, variation between a current which flows through the first dummy cell 5 and a current which flows through the second dummy cell 6 can be canceled out. According to the fifth embodiment, the number of first dummy cells 5 and second dummy cells 6 can be reduced, and thus the size of a semiconductor memory device can be reduced.

### SIXTH EMBODIMENT

In a sixth embodiment, if a dummy cell has a defect, a dummy bit line to which the dummy cell is connected is replaced with a spare bit line.

FIG. 14 is a block diagram showing the schematic configuration of a semiconductor memory device according to the sixth embodiment of the present invention. Ones of the components in FIG. 14 that are shared with FIG. 9 are denoted by the same reference numerals as those in FIG. 9. In the following description, an explanation will be given with a focus on differences between FIGS. 14 and 9.

The semiconductor memory device in FIG. 14 is obtained by adding, to the configuration in FIG. 9, spare bit lines 61 and 62, each of which serves as a replacement for a dummy bit line if a dummy cell connected to the dummy bit line has a defect. The spare bit lines 61 and 62 are arranged adjacent to dummy bit lines 5 and 6, respectively. The example in FIG. 14 has the first spare bit lines 61 which serve as replacements for the first dummy bit lines 5 and the second spare bit lines 62 which serve as replacements for the second dummy bit lines 62.

Spare cells 63 and a transistor 64 which controls writing of data to the spare cells 63 are connected to each first spare bit line 61. Each transistor 64 is connected to a first dummy bit line clamping circuit 7. Spare cells 65 and a transistor 66 which controls writing of data to the spare cells 65 are connected to each second spare bit line 62. Each transistor 66 is connected to a second dummy bit line clamping circuit 8.

If any of dummy cells which are connected to the first dummy bit lines 5 and second dummy bit lines 6 has a defect, the whole of the first or second dummy bit line connected to the dummy cell is replaced with the corresponding first or second spare bit line 61 or 62. More specifically, if any of the dummy cells connected to one of the first dummy bit lines 5 has a defect, a corresponding first transistor 12 is turned off, and the corresponding transistor 64 is turned on instead. With this operation, the first dummy bit line is replaced with the corresponding spare bit line 61.

As described above, according to the sixth embodiment, if one of the dummy cells has a defect, the whole of the dummy bit line to which the dummy cell is connected is replaced with a corresponding one of the first and second spare bit lines 61 and 62. This makes it possible to prevent a malfunction caused by a defective dummy cell and improve the yield of semiconductor memory devices.

### SEVENTH EMBODIMENT

A seventh embodiment can inhibit writing to a defective one (if any) of first dummy cells 5 or second dummy cells 6.

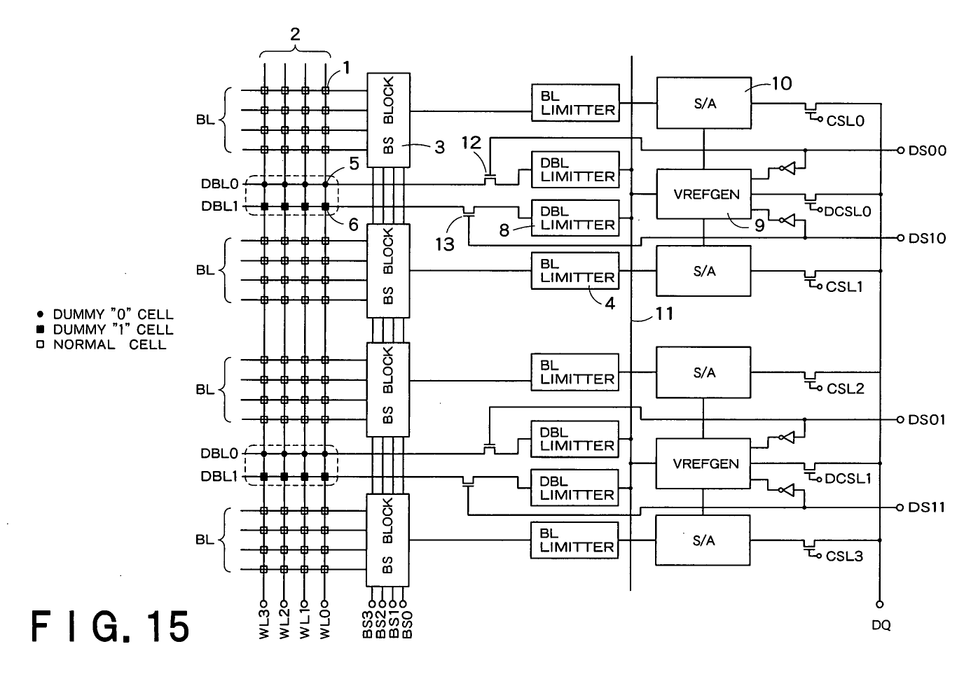

FIG. 15 is a block diagram showing the schematic configuration of a semiconductor memory device according to the seventh embodiment of the present invention. Ones of the components in FIG. 15 that are shared with FIG. 1 are denoted by the same reference numerals as those in FIG. 1. In the following description, an explanation will be given with a focus on differences between FIGS. 15 and 9.

In FIG. 15, first transistors 12 and second transistors 13 are connected in a different manner from that of FIG. 9. Turning on/off of the first and second transistors 12 and 13 in FIG. 15 can be separately controlled. With this configuration, if some of the first dummy cells 5 or second dummy cells 6 are defective, writing of data to the defective dummy cells can be inhibited.

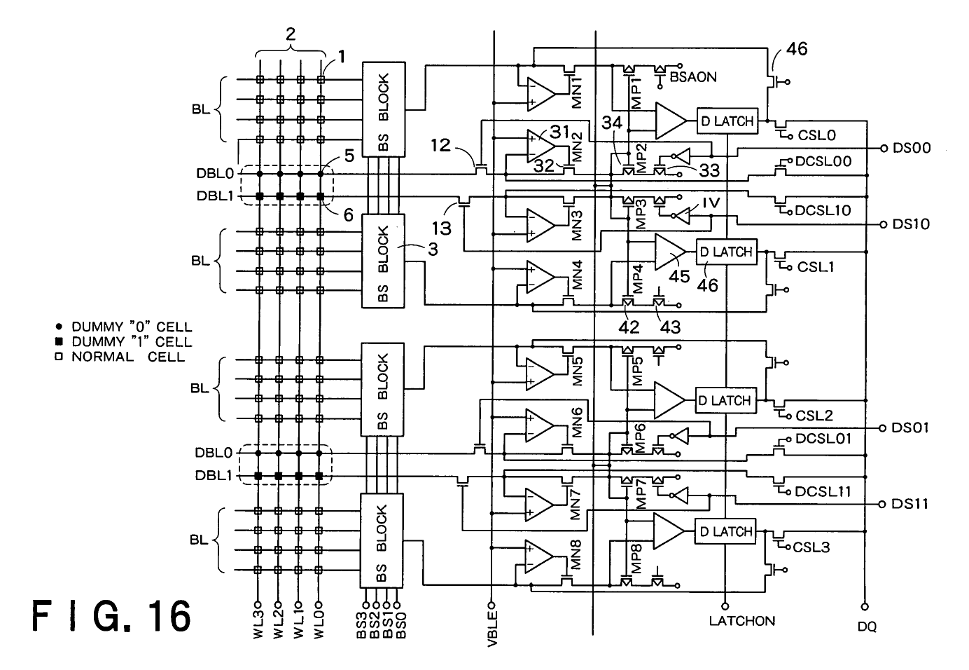

FIG. 16 is a circuit diagram showing in more detail the semiconductor memory device in FIG. 15. Signals DS00, DS10, DS01, and DS11 to be input to gates of the first and second transistors 12 and 13 are also input to gates of PMOS transistors 34 in corresponding reference potential generation circuits 9 through inverters IV. This stops the operation of the reference potential generation circuit 9 corresponding to one of the dummy cells targeted for inhibition of data writing and enables a reduction in power consumption.

As described above, the fifth embodiment is configured to inhibit writing of data to a defective dummy cell and thus enables a reduction in power consumption.

Note that although not shown in FIGS. 15 and 16, spare bit lines which serve as replacements for dummy bit lines may be provided, as shown in FIG. 14.

### EIGHTH EMBODIMENT

The eighth embodiment is a modification of the seventh embodiment.

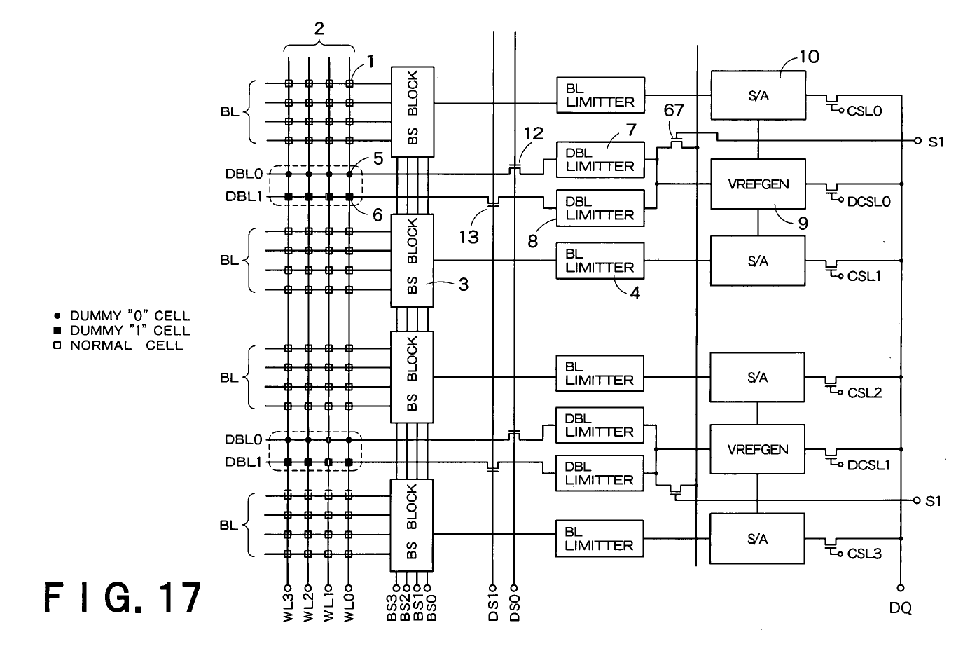

FIG. 17 is a block diagram showing a schematic configuration of a semiconductor memory device according to an eighth embodiment of the present invention. Ones of the components in FIG. 17 that are shared with FIG. 1 are denoted by the same reference numerals as those in FIG. 1. In the following description, an explanation will be given with a focus on differences between FIGS. 17 and 1.

The semiconductor memory device in FIG. 17 is obtained by newly adding transistors 67 to the configuration in FIG. 1. Each transistor 67 switches whether the writing data should be supplied to the common connecting line 11 to which first and second dummy bit line clamping circuits 7 and 8 are connected. Each transistor 67 is provided for each combination of a first dummy bit line DBL0 and a corresponding second dummy bit line DBL1.

Accordingly, if any one of the transistors 67 is turned off, it is possible to inhibit data writing for the first dummy cell 5 and the second dummy cell 6 corresponding to the turned-off transistor 67.

As described above, in the sixth embodiment, writing of data to dummy cells can be inhibited by simpler control than the fifth embodiment. Note that spare bit lines as shown in FIG. 14 may be provided for FIG. 17. The transistor 67 in FIG. 17 may be added to the semiconductor memory device in FIG. 11.

What is claimed is:

1. A semiconductor memory device, comprising:
a memory cell array which has a plurality of memory cells;
first dummy bit lines arranged at a predetermined interval by sandwiching at least one bit line therebetween;
second dummy bit lines arranged at a predetermined interval by sandwiching at least one bit line therebetween;
first dummy cells each of which is connected to the corresponding first dummy bit line and generates a reference current for data “0”;
second dummy cells each of which is connected to the corresponding second dummy bit line and generates a reference current for data “1”;
first dummy bit line clamping circuits each of which limits a potential of the corresponding first dummy bit line to be equal to or less than a predetermined potential;
second dummy bit line clamping circuits each of which limits a potential of the corresponding second dummy bit line to be equal to or less than the predetermined potential;
reference potential generation circuits each of which generates a reference potential based on output currents of the corresponding first and second dummy bit line clamping circuits;
sense amplifiers each of which detects logics of data stored in a selected memory cell based on a potential difference between an output current of the selected memory cell and the reference current; and
a common connecting line which connects an output terminal of the corresponding first dummy bit clamping circuit, an output terminal of the corresponding second dummy bit clamping circuit and an input terminal of the corresponding reference potential generation circuit.

2. A semiconductor memory device according to claim 1,
wherein each of the sense amplifiers includes:
a first sense circuit which generates a data potential based on a current difference between the output current of the selected memory cell and the reference current; and
a second sense circuit which detects logics of data stored in the selected memory cell based on data potential outputted from the first sense circuit and the reference potential.

3. A semiconductor memory device according to claim 1, further comprising:
first transistors each of which controls data writing to the corresponding first dummy cell; and
second transistors each of which controls data writing to the corresponding second dummy cell.

4. A semiconductor memory device according to claim 1,
wherein each of the first transistors is controlled to ON or OFF for each of the first dummy bit lines; and
each of the second transistors is controlled to ON or OFF for each of the second dummy bit lines.

5. A semiconductor memory device according to claim 1,
wherein the common connecting line connects at least two of the output terminals of the first dummy bit line clamping circuits, the output terminals of the corresponding second dummy bit line clamping circuits and the input terminals of the corresponding reference potential generation circuits.

6. A semiconductor memory device according to claim 1,
wherein each the first dummy bit line and the corresponding second dummy bit line are arranged by sandwiching the corresponding bit line therebetween.

7. A semiconductor memory device according to claim 1,
wherein each of the first dummy bit line clamping circuits has the same size, shape, circuit configuration and electrical properties as those of the corresponding second dummy bit line clamping circuit.

8. A semiconductor memory device according to claim 1,
wherein gate widths and gate lengths of transistors in each of the first dummy bit line clamping circuit are equal to those of transistors in each of the second dummy bit line clamping circuit.

9. A semiconductor memory device according to claim 1,
wherein each of the first dummy bit line clamping circuits includes:
a first differential amplifier which outputs a signal in accordance with a potential difference between the potential of the corresponding first dummy bit line and the reference potential; and
a first transistor which performs negative feedback control on the potential of the corresponding first dummy bit line based on the output of the first differential amplifier, each of the second dummy bit line clamping circuits includes:
a second differential amplifier which outputs a signal in accordance with a potential difference between the potential of the corresponding second dummy bit line and the reference potential; and
a second transistor which performs negative feedback control on the potential of the corresponding second dummy bit line based on the output of the second differential amplifier.

10. A semiconductor memory device according to claim 1, further comprising:
a first spare cell and a first spare bit line capable of replacing a defective first dummy cell in units of each of the first dummy bit lines;
a second spare cell and a second spare bit line capable of replacing a defective second dummy cell in units of each of the second dummy bit lines;
a first transistor which controls whether the first spare bit line should be connected to the corresponding first dummy bit line clamping circuit; and
a second transistor which controls whether the second spare bit line should be connected to the second dummy bit clamping circuit.

11. A semiconductor memory device according to claim 1, further comprising a transistor which controls switching of whether the common connecting line is connected to the reference potential generation circuit.

12. A semiconductor memory device according to claim 1, further comprising holding circuits each of which holds the output of the corresponding sense amplifier.

13. A semiconductor memory device according to claim 1, wherein each of the memory cell arrays is an FBC (Floating Body Cell).

14. A semiconductor memory device, comprising:
a memory cell array which has a plurality of memory cells;
a plurality of bit lines connected to the memory cells;
a plurality of dummy bit lines each of which is arranged at a predetermined interval by sandwiching at least one bit line therebetween;
first dummy cells each of which is connected to the corresponding dummy bit line and generates a reference current for data “0”;
second dummy cells each of which is connected to the corresponding dummy bit line and generates a reference current for data “1”;
clamping circuits each of which limits a potential of the corresponding dummy bit line to be equal to or less than a predetermined potential;
reference potential generation circuits each of which generates a reference potential based on an output current of the corresponding clamping circuit;
sense amplifiers each of which detects logics of data stored in the selected memory cell based on the reference current and the reference potential; and
a common connecting line which connects an output terminal of the clamping circuit corresponding to the plurality of dummy bit lines and an input terminal of the corresponding reference potential generation circuit.

15. A semiconductor memory device according to claim 14,
wherein the sense amplifier includes:
a first sense circuit which generates a data potential based on a current difference between the output current of the selected memory cell and the reference current; and
a second sense circuit which detects logics of data stored in the selected memory cell based on data potential outputted from the first sense circuit and the reference potential.

16. A semiconductor memory device according to claim 14,
wherein whether the common connecting line is connected to the reference potential generating circuit is controlled.

17. A semiconductor memory device according to claim 14, further comprising a holding circuit which holds an output of the corresponding sense amplifier.

18. A semiconductor memory device according to claim 14, wherein each of the memory cell arrays is an FBC (Floating Body Cell).
